(19) United States
(12) Patent Application Publication
(10) Pub. No.: US 2026/0059659 A1
(43) Pub. Date: Feb. 26, 2026

(54) ELECTRONIC ASSEMBLY, SOLDERING BOARD, AND OXYGEN-FREE COPPER LAYER

(71) Applicant: TONG HSING ELECTRONIC INDUSTRIES, LTD., Taoyuan City (TW)

(72) Inventors: Ting-An Yang, Taoyuan City (TW); CHI-WEN HUANG, Taoyuan City (TW); CHUNG-HO WEI, Taoyuan City (TW); MING-YI HSU, Taoyuan City (TW)

(21) Appl. No.: 18/941,344

(22) Filed: Nov. 8, 2024

(30) Foreign Application Priority Data
Aug. 21, 2024 (TW) 113131367

(51) Int. Cl. H05K 1/09; H05K 1/11; H05K 1/18

(52) U.S. Cl. CPC H05K 1/09; H05K 1/11; H05K 1/181

(57) ABSTRACT

An electronic assembly, a soldering board, and an oxygen-free copper layer are provided. The oxygen-free copper layer has a plurality of soldering surfaces and an anti-soldering surface that is connected to the soldering surfaces. Each of the soldering surfaces has a first arithmetic mean roughness (Ra) and a first maximum height roughness (Rz), and the anti-soldering surface has a second Ra and a second Rz. The second Ra is greater than the first Ra, and a Ra difference between the second Ra and the first Ra is within a range from 0.15 μm to 10 μm. The second Rz is greater than the first Rz, and a Rz difference between the second Rz and the first Rz is within a range from 0.5 μm to 16 μm. The anti-soldering surface is configured to block a solder in a melted state from flowing thereon.

### CROSS-REFERENCE TO RELATED PATENT APPLICATION

This application claims the benefit of priority to Taiwan Patent Application No. 113131367, filed on Aug. 21, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an anti-soldering metal structure, and more particularly to an electronic assembly, a soldering board, and an oxygen-free copper layer.

### BACKGROUND OF THE DISCLOSURE

While a conventional soldering board is often provided with insulating materials for soldering protection, this can lead to numerous restrictions and inconveniences. For example, when two solder pads of the conventional soldering board are in close proximity to each other, an insulating solder mask cannot be accurately formed with two holes respectively corresponding in position to the two solder pads. Furthermore, the insulating solder mask can easily have issues such as delamination, peeling, cracking, and contamination of solder pads.

### SUMMARY OF THE DISCLOSURE

In response to the above-referenced technical inadequacies, the present disclosure provides an electronic assembly, a soldering board, and an oxygen-free copper layer for effectively improving on the issues associated with conventional soldering boards.

In order to solve the above-mentioned problems, one of the technical aspects adopted by the present disclosure is to provide an electronic assembly, which includes a soldering board, a plurality of solders, and an electronic component. The soldering board includes a carrier layer and an oxygen-free copper layer formed on the carrier layer. The oxygen-free copper layer has a plurality of soldering surfaces and an anti-soldering surface. Each of the soldering surfaces has a first arithmetic mean roughness (Ra) and a first maximum height roughness (Rz). The anti-soldering surface is connected to the soldering surfaces. A lowest point of the anti-soldering surface and any one of the soldering surfaces have a height difference therebetween that is less than 50 μm, the oxygen-free copper layer is provided without any insulating layer on the anti-soldering surface thereof, and the anti-soldering surface has a second Ra and a second Rz. The second Ra is greater than the first Ra, and a Ra difference between the second Ra and the first Ra is within a range from 0.15 μm to 10 μm. The second Rz is greater than the first Rz, and a Rz difference between the second Rz and the first Rz is within a range from 0.5 μm to 16 μm. The solders are respectively fixed to the soldering surfaces of the oxygen-free copper layer. The electronic component is fixed to the solders and is electrically coupled to the oxygen-free copper layer. The anti-soldering surface is configured to block the solders in a melted state from flowing thereon through the Ra difference and the Rz difference.

In order to solve the above-mentioned problems, another one of the technical aspects adopted by the present disclosure is to provide a soldering board, which includes a carrier layer and an oxygen-free copper layer formed on the carrier layer. The oxygen-free copper layer has a plurality of soldering surfaces and an anti-soldering surface. Each of the soldering surfaces has a first arithmetic mean roughness (Ra) and a first maximum height roughness (Rz), and each of the soldering surfaces is configured to allow a solder placed thereon. The anti-soldering surface is connected to the soldering surfaces. A lowest point of the anti-soldering surface and any one of the soldering surfaces have a height difference therebetween that is less than 50 μm, the oxygen-free copper layer is provided without any insulating layer on the anti-soldering surface thereof, and the anti-soldering surface has a second Ra and a second Rz. The second Ra is greater than the first Ra, and a Ra difference between the second Ra and the first Ra is within a range from 0.15 μm to 10 μm, and wherein the second Rz is greater than the first Rz, and a Rz difference between the second Rz and the first Rz is within a range from 0.5 μm to 16 μm. The anti-soldering surface is configured to block the solder in a melted state from flowing thereon through the Ra difference and the Rz difference.

In order to solve the above-mentioned problems, yet another one of the technical aspects adopted by the present disclosure is to provide an oxygen-free copper layer, which has a plurality of soldering surfaces and an anti-soldering surface. Each of the soldering surfaces has a first arithmetic mean roughness (Ra) and a first maximum height roughness (Rz), and each of the soldering surfaces is configured to allow a solder placed thereon. The anti-soldering surface is connected to the soldering surfaces. A lowest point of the anti-soldering surface and any one of the soldering surfaces have a height difference therebetween that is less than 50 μm, the oxygen-free copper layer is provided without any insulating layer on the anti-soldering surface thereof, and the anti-soldering surface has a second Ra and a second Rz. The second Ra is greater than the first Ra, and a Ra difference between the second Ra and the first Ra is within a range from 0.15 μm to 10 μm. The second Rz is greater than the first Rz, and a Rz difference between the second Rz and the first Rz is within a range from 0.5 μm to 16 μm. The anti-soldering surface is configured to block the solder in a melted state from flowing thereon through the Ra difference and the Rz difference.

Therefore, through the anti-soldering surface that meets specific structural conditions and that is made of an oxygen-free copper material, any one of the electronic assembly, the soldering board, and the oxygen-free copper layer provided by the present disclosure can be used to block the solders from flowing on the anti-soldering surface, so that any insulating solder mask does not need to be arranged around the anti-soldering surface, thereby effectively avoiding the issues associated with a conventional insulating solder mask (e.g., the issues of delamination, peeling, cracking, and the contamination of solder pads).

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of an electronic assembly according to an embodiment of the present disclosure;

FIG. 2 is a schematic cross-sectional view taken along line II-II of FIG. 1;

FIG. 3 is a schematic top view of FIG. 2;

FIG. 4 is a schematic top view of a soldering board according to the embodiment of the present disclosure;

FIG. 5 is a schematic top view showing the electronic assembly in another configuration according to the embodiment of the present disclosure;

FIG. 6 is a schematic top view showing the soldering board of FIG. 5;

FIG. 7 is a schematic top view showing the electronic assembly in yet another configuration according to the embodiment of the present disclosure; and

FIG. 8 is a schematic top view showing the soldering board of FIG. 7.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on. ” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

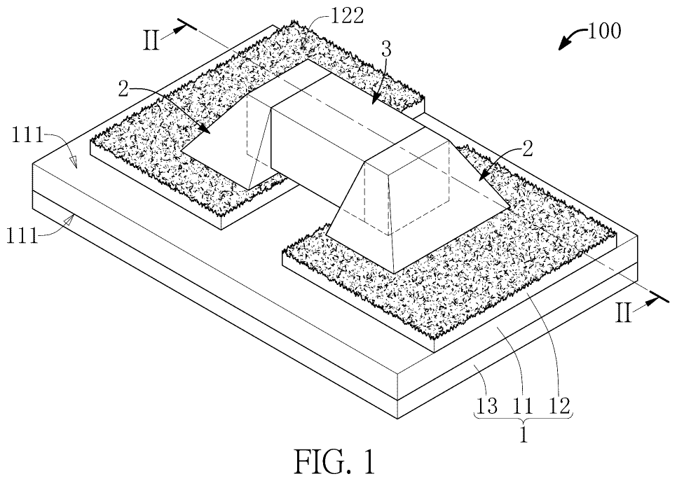

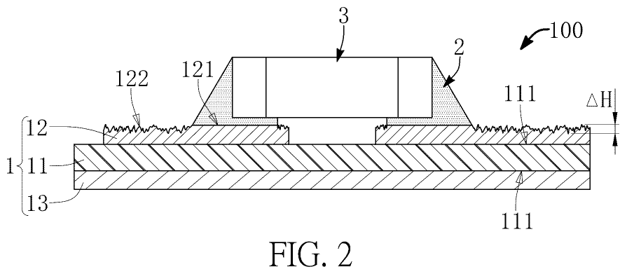

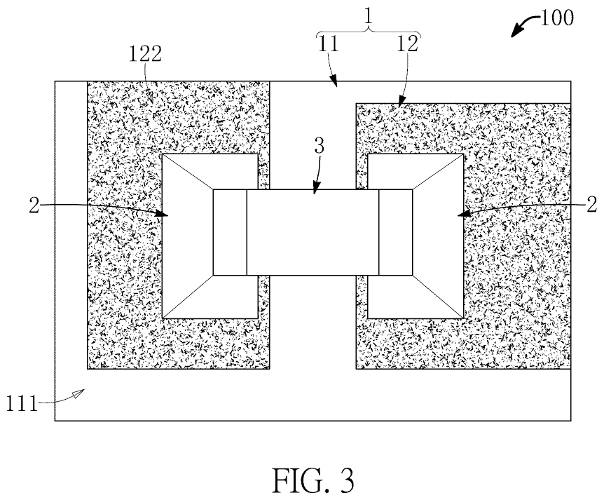

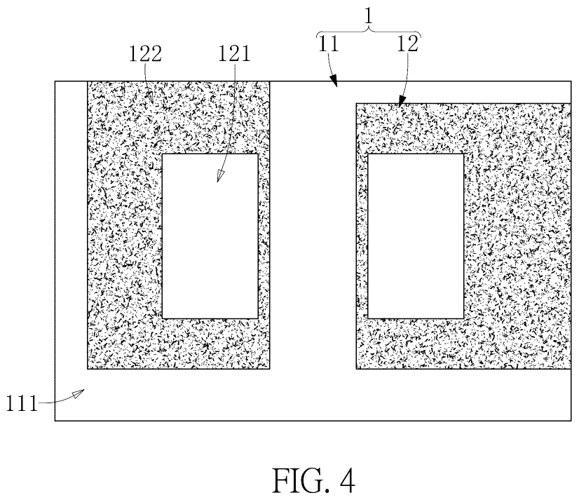

Referring to FIG. 1 to FIG. 8, an embodiment of the present disclosure is provided. As shown in FIG. 1 to FIG. 4, the present embodiment provides an electronic assembly 100, which includes a soldering board 1, a plurality of solders 2 fixed to the soldering board 1, and an electronic component 3 that is fixed to the solders 2, but the present disclosure is not limited thereto. For example, in other embodiments of the present disclosure not shown in the drawings, the soldering board 1 can be independently used (e.g., sold) or can be used in cooperation with other components according to practical requirements. Moreover, the drawings of the present embodiment only show a part of the soldering board 1 for ease of description.

In the present embodiment, the soldering board 1 is preferably provided without any insulating solder mask, and the soldering board 1 includes a carrier layer 11, an oxygen-free copper layer 12 formed on one side of the carrier layer 11, and a copper layer 13 that is formed on another side of the carrier layer 11. The carrier layer 11 can be a ceramic board and has two board surfaces 111 opposite to each other, and the copper layer 13 is preferably made of an oxygen-free copper, but the present disclosure is not limited thereto.

Specifically, the oxygen-free copper layer 12 and the copper layer 13 are respectively formed on the two board surfaces 111 of the carrier layer 11 in an active metal brazing (AMB) manner and are respectively two AMB layers; or, the oxygen-free copper layer 12 and the copper layer 13 are respectively formed on the two board surfaces 111 of the carrier layer 11 in a direct plated copper (DPC) manner and are respectively two DPC layers; or, the oxygen-free copper layer 12 and the copper layer 13 are respectively eutectic-bonded on the two board surfaces 111 of the carrier layer 11 in a direct bonded copper (DBC) manner and are respectively two DBC layers, but the present disclosure is not limited thereto.

For example, in other embodiments of the present disclosure not shown in the drawings, the soldering board 1 can be a printed circuit board (PCB); or, the oxygen-free copper layer 12 can be independently used (e.g., sold) or can be used in cooperation with other components (e.g., the oxygen-free copper layer 12 can be a lead frame in cooperation with other components) according to practical requirements.

In the present embodiment, (outer surfaces of) the oxygen-free copper layer 12 includes a plurality of soldering surfaces 121 and an anti-soldering surface 122 that is connected to the soldering surfaces 121, and the oxygen-free copper layer 12 is provided without any insulating layer on the anti-soldering surface 122 thereof. In other words, an anti-soldering effect of the anti-soldering surface 122 is provided through a metal material (e.g., an oxygen-free copper). Accordingly, any anti-soldering surface having a non-metal material is different from the anti-soldering surface 122 of the oxygen-free copper layer 12 provided by the present embodiment. The anti-soldering surface 122 includes two segments that are separated (or spaced apart) from each other and that are respectively connected to the soldering surfaces 121, but the present disclosure is not limited thereto.

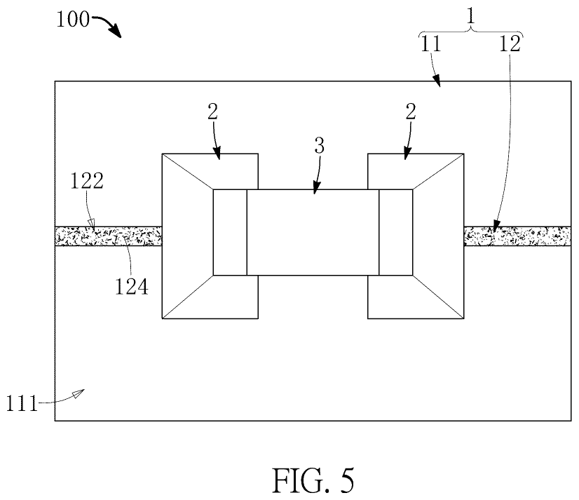

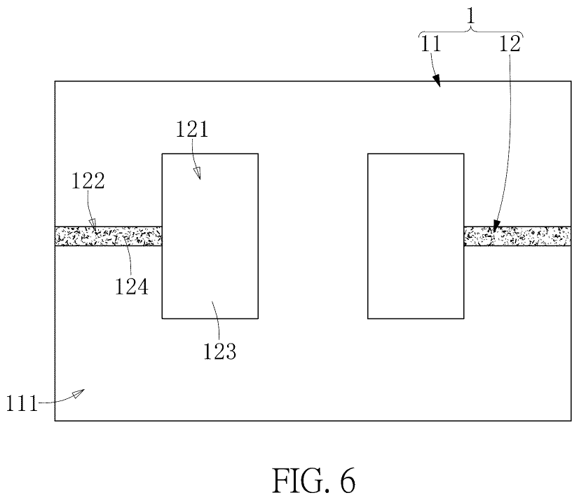

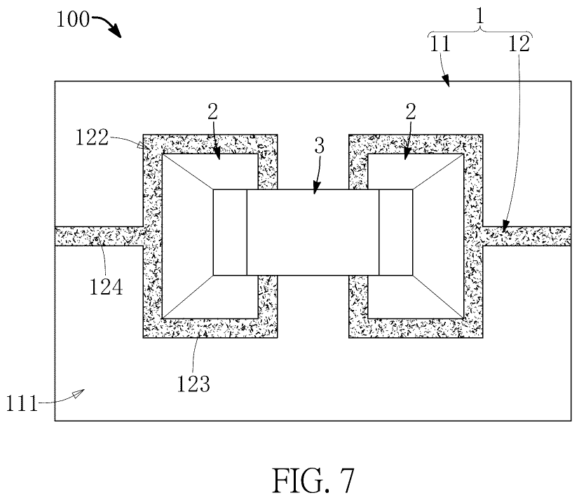

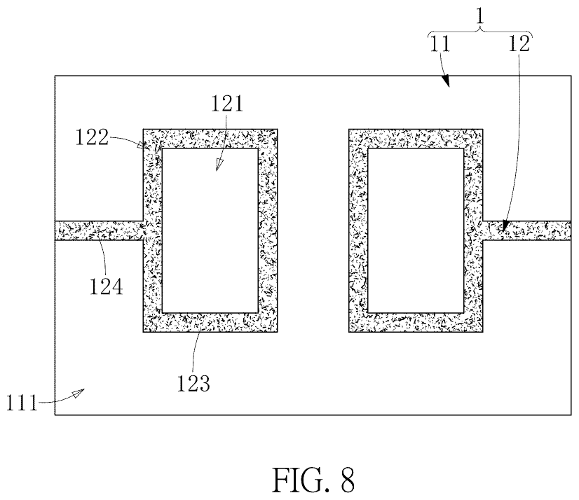

Moreover, the connection relationship between the soldering surfaces 121 and the anti-soldering surface 122 can be adjusted or changed according to practical requirements, but the present disclosure is not limited thereto. For example, as shown in FIG. 5 and FIG. 6, each of the soldering surfaces 121 is connected to the anti-soldering surface 122 through an edge thereof, and other edges of each of the soldering surfaces 121 are not connected to any metal material; or, as shown in FIG. 7 and FIG. 8, any one of the soldering surfaces 121 can be surrounded by the anti-soldering surface 122.

In other words, the oxygen-free copper layer 12 can include a plurality of soldering pads 123 and a plurality of signal transmission circuits 124 that are connected to the soldering pads 123 according to practical requirements. As shown in FIG. 5 and FIG. 6, the soldering surfaces 121 are outer surfaces of the soldering pads 123, and the anti-soldering surface 122 includes outer surfaces of the signal transmission circuits 124. Or, as shown in FIG. 7 and FIG. 8, each of the soldering surfaces 121 is a part of the outer surface of one of the soldering pads 123, and the anti-soldering surface 122 includes other parts of each of the soldering pads 123 and the outer surfaces of the signal transmission circuits 124. In the present embodiment, the outer surfaces of the signal transmission circuits 124 are provided with the anti-soldering function, such that the signal transmission circuits 124 do not need to be covered by an insulating solder mask.

As shown in FIG. 1 to FIG. 4, the anti-soldering surface 122 of the oxygen-free copper layer 12 is provided with the anti-soldering function through at least part of the following features, but the present disclosure is not limited thereto. Each of the soldering surfaces 121 has a first arithmetic mean roughness (Ra) and a first maximum height roughness (Rz), and the anti-soldering surface has a second Ra and a second Rz.

Moreover, the second Ra is greater than the first Ra, and a Ra difference between the second Ra and the first Ra is within a range from 0.15 μm to 10 μm. The second Rz is greater than the first Rz, and a Rz difference between the second Rz and the first Rz is within a range from 0.5 μm to 16 μm. Furthermore, a lowest point of the anti-soldering surface 122 and any one of the soldering surfaces 121 have a height difference ΔH therebetween that is less than 50 μm.

In summary, the anti-soldering surface 122 is configured to block any one of the solders 2 in a melted state from flowing thereon through the Ra difference and the Rz difference. In other words, any anti-soldering surface not meeting the conditions defined by the data provided above is different from the anti-soldering surface 122 of the oxygen-free copper layer 12 provided by the present embodiment.

Accordingly, the soldering board 1 (or the oxygen-free copper layer 12) in the present embodiment can be used to block the solders 2 from flowing thereon through the anti-soldering surface 122 that meets specific structural conditions and that is made of an oxygen-free copper material, so that any insulating solder mask does not need to be arranged around the anti-soldering surface 122, thereby effectively avoiding the issues associated with the insulating solder mask (e.g., the issues of delamination, peeling, cracking, and the contamination of solder pads).

In order to enable the anti-soldering surface 122 of the oxygen-free copper layer 12 to effectively block the solders 2 from flowing thereon, the structural conditions of the oxygen-free copper layer 12 can meet at least part of the following features: the Ra difference is preferably within a range from 0.15 μm to 1 μm, the Rz difference is preferably within a range from 0.5 μm to 5 μm, and the height difference ΔH is preferably greater than 0 and less than 10 μm, but the present disclosure is not limited thereto.

In addition, the above description describes the structure of the soldering board 1, and the following description approximately describes a manufacturing method of the oxygen-free copper layer 12 of the soldering board 1, but the present disclosure is not limited thereto. The soldering surfaces 121 of the oxygen-free copper layer 12 are covered by a dry film or a photoresist (PR) layer, and then portions of the oxygen-free copper layer 12 not covered by the dry film or the PR layer are roughened to form the anti-soldering surface 122. The roughening manner of the oxygen-free copper layer 12 can be implemented in a physical roughening manner or a chemical roughening manner. For example, the roughening manner can be implemented through chemical etching, plasma etching, mechanical polishing, CNC grinding, sandblasting, or grinding wheel abrasion.

The solders 2 are respectively fixed to the soldering surfaces 121 of the oxygen-free copper layer 12. In the present embodiment, each of the solders 2 is a solder paste; or, each of the solders 2 includes a solder ball and a flux. Moreover, the electronic component 3 is fixed to the solders 2 and is electrically coupled to the oxygen-free copper layer 12. The anti-soldering surface 122 is configured to block the solders 2 in a melted state (e.g., when the solders 2 are in the melted state during a reflow process) from flowing thereon through the Ra difference and the Rz difference.

### Beneficial Effects of the Embodiment

In conclusion, through the anti-soldering surface that meets specific structural conditions and that is made of an oxygen-free copper material, any one of the electronic assembly, the soldering board, and the oxygen-free copper layer provided by the present disclosure can be used to block the solders from flowing on the anti-soldering surface, so that any insulating solder mask does not need to be arranged around the anti-soldering surface, thereby effectively avoiding the issues associated with a conventional insulating solder mask (e.g., the issues of delamination, peeling, cracking, and the contamination of solder pads).

In addition, the anti-soldering surface in the present disclosure is formed by roughening a partial surface of the oxygen-free copper layer so as to block the solders in the melted state from flowing thereon.

Compared with the conventional technique of using a roughened oxygen-containing copper surface to form an anti-soldering surface, the present disclosure can avoid disadvantages associated with the conventional anti-soldering surface that is formed by roughening an oxygen-containing copper surface. For example, after the conventional anti-soldering surface is cleaned in a plasma manner or a solder flux and organic compounds manner, the roughened oxygen-containing copper of the conventional anti-soldering surface is removed and the solder mask function is lost.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An electronic assembly, comprising:
a soldering board including:
a carrier layer; and
an oxygen-free copper layer formed on the carrier layer and including:
a plurality of soldering surfaces each having a first arithmetic mean roughness (Ra) and a first maximum height roughness (Rz); and
an anti-soldering surface connected to the soldering surfaces, wherein a lowest point of the anti-soldering surface and any one of the soldering surfaces have a height difference therebetween that is less than 50 μm, the oxygen-free copper layer is provided without any insulating layer on the anti-soldering surface thereof, and the anti-soldering surface has a second Ra and a second Rz;
wherein the second Ra is greater than the first Ra, and a Ra difference between the second Ra and the first Ra is within a range from 0.15 μm to 10 μm, and wherein the second Rz is greater than the first Rz, and a Rz difference between the second Rz and the first Rz is within a range from 0.5 μm to 16 μm;
a plurality of solders respectively fixed to the soldering surfaces of the oxygen-free copper layer; and
an electronic component fixed to the solders and electrically coupled to the oxygen-free copper layer, wherein the anti-soldering surface is configured to block the solders in a melted state from flowing thereon through the Ra difference and the Rz difference.

2. The electronic assembly according to claim 1, wherein the Ra difference is within a range from 0.15 μm to 1 μm, the Rz difference is within a range from 0.5 μm to 5 μm, and the height difference is greater than 0 and less than 10 μm.

3. The electronic assembly according to claim 1, wherein the carrier layer is a ceramic board, and the soldering board further includes a copper layer, and wherein the oxygen-free copper layer and the copper layer are respectively formed on two board surfaces of the carrier layer in an active metal brazing (AMB) manner and are respectively two AMB layers.

4. The electronic assembly according to claim 1, wherein the carrier layer is a ceramic board, and the soldering board further includes a copper layer, and wherein the oxygen-free copper layer and the copper layer are each a direct plated copper (DPC) layer and are formed on two board surfaces of the carrier layer in a DPC manner, respectively.

5. The electronic assembly according to claim 1, wherein the carrier layer is a ceramic board, and the soldering board further includes a copper layer, and wherein the oxygen-free copper layer and the copper layer are each a direct bonded copper (DBC) layer and are eutectic-bonded on two board surfaces of the carrier layer in a DBC manner, respectively.

6. The electronic assembly according to claim 1, wherein the soldering surfaces are surrounded by the anti-soldering surface, and the oxygen-free copper layer includes a plurality of soldering pads and a plurality of signal transmission circuits that are connected to the soldering pads, and wherein the soldering surfaces are outer surfaces of the soldering pads, and the anti-soldering surface includes outer surfaces of the signal transmission circuits.

7. The electronic assembly according to claim 1, wherein no insulating solder mask is provided on the soldering board.

8. The electronic assembly according to claim 1, wherein each of the solders is a solder paste; or, each of the solders includes a solder ball and a flux.

9. A soldering board, comprising:
a carrier layer; and
an oxygen-free copper layer formed on the carrier layer and including:
a plurality of soldering surfaces each having a first arithmetic mean roughness (Ra) and a first maximum height roughness (Rz), wherein each of the soldering surfaces is configured to allow a solder placed thereon; and
an anti-soldering surface connected to the soldering surfaces, wherein a lowest point of the anti-soldering surface and any one of the soldering surfaces have a height difference therebetween that is less than 50 μm, the oxygen-free copper layer is provided without any insulating layer on the anti-soldering surface thereof, and the anti-soldering surface has a second Ra and a second Rz;
wherein the second Ra is greater than the first Ra, and a Ra difference between the second Ra and the first Ra is within a range from 0.15 μm to 10 μm, and wherein the second Rz is greater than the first Rz, and a Rz difference between the second Rz and the first Rz is within a range from 0.5 μm to 16 μm;
wherein the anti-soldering surface is configured to block the solder in a melted state from flowing thereon through the Ra difference and the Rz difference.

10. An oxygen-free copper layer, comprising:
a plurality of soldering surfaces each having a first arithmetic mean roughness (Ra) and a first maximum height roughness (Rz), wherein each of the soldering surfaces is configured to allow a solder placed thereon; and
an anti-soldering surface connected to the soldering surfaces, wherein a lowest point of the anti-soldering surface and any one of the soldering surfaces have a height difference therebetween that is less than 50 μm, the oxygen-free copper layer is provided without any insulating layer on the anti-soldering surface thereof, and the anti-soldering surface has a second Ra and a second Rz;
wherein the second Ra is greater than the first Ra, and a Ra difference between the second Ra and the first Ra is within a range from 0.15 μm to 10 μm, and wherein the second Rz is greater than the first Rz, and a Rz difference between the second Rz and the first Rz is within a range from 0.5 μm to 16 μm;
wherein the anti-soldering surface is configured to block the solder in a melted state from flowing thereon through the Ra difference and the Rz difference.
